(19) United States
(12) Patent Application Publication
(10) Pub. No.: US 2026/0231739 A1
(43) Pub. Date: Aug. 6, 2026

(54) METHOD FOR MANUFACTURING SEMICONDUCTOR SUBSTRATE

(71) Applicant: JSR CORPORATION, Tokyo (JP)

(72) Inventors: Ryuichi SERIZAWA, Tokyo (JP); Hironori KIMATA, Tokyo (JP); Yuki OZAKI, Tokyo (JP)

(73) Assignee: JSR CORPORATION, Tokyo (JP)

(21) Appl. No.: 19/630,590

(22) Filed: Mar. 27, 2026

Related U.S. Application Data
(63) Continuation-in-part of application No. PCT/JP2024/035444, filed on Oct. 3, 2024.

(30) Foreign Application Priority Data
Oct. 13, 2023 (JP) 2023-177280

(51) Int. Cl. H10P 76/40; G03F 7/00; G03F 7/004; G03F 7/20; H10P 14/60

(52) U.S. Cl. CPC H10P 76/40; G03F 7/0042; G03F 7/2004; G03F 7/70033; H10P 14/6532

(57) ABSTRACT

A method for manufacturing a semiconductor substrate includes: applying a composition for film formation to a substrate to form a coating film, and subjecting the coating film to at least one process selected from the group consisting of radiation exposure and plasma exposure. The composition for film formation includes: a metal compound comprising a metal atom and an organic acid, and a solvent.

### CROSS-REFERENCE TO RELATED APPLICATIONS

The present application is a continuation-in-part application of International Patent Application No. PCT/JP2024/035444 filed Oct. 3, 2024, which claims priority to Japanese Patent Application No. 2023-177280 filed Oct. 13, 2023. The contents of these applications are incorporated herein by reference in their entirety.

### BACKGROUND OF THE DISCLOSURE

### Technical Field

The present disclosure relates to a method for manufacturing a semiconductor substrate.

### Background Art

A semiconductor device is produced using, for example, a multilayer resist process in which a resist pattern is formed by exposing to light and developing a resist film laminated on a substrate with a resist underlayer film, such as an organic underlayer film or a silicon-containing film, being interposed between them. In this process, the resist underlayer film is etched using this resist pattern as a mask, and the substrate is further etched using the obtained resist underlayer film pattern as a mask so that a desired pattern is formed on the substrate to obtain a patterned substrate (see JP-A-2004-177668).

In recent years, metal hardmask compositions have been proposed as a resist underlayer film (see JP-A-2013-185155).

### SUMMARY

According to an aspect of the present disclosure, a method for manufacturing a semiconductor substrate includes: applying a composition for film formation to a substrate to form a coating film, and subjecting the coating film to at least one process selected from the group consisting of radiation exposure and plasma exposure. The composition for film formation includes: a metal compound comprising a metal atom and an organic acid (hereinafter also referred to as “compound [A]”), and a solvent (hereinafter also referred to as “solvent [B]”).

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

In the present specification, an “organic group” means a group having at least one carbon atom.

Recently, substrates on which a pattern such as a trench or a hole is formed are often used, and metal hardmask compositions are required to form a metal hardmask capable of sufficiently embedding a pattern of a substrate. However, conventional metal hardmask compositions cannot satisfy these requirements.

By the method for manufacturing a semiconductor substrate, since a resist underlayer film superior in embeddability is formed, a well patterned semiconductor substrate can be obtained. Therefore, the method for manufacturing a semiconductor substrate can suitably be used for, for example, manufacturing semiconductor devices expected to be further microfabricated in the future.

### <<Method for Manufacturing Semiconductor Substrate>>

The method for manufacturing a semiconductor substrate includes applying a composition for film formation to a substrate (hereinafter also referred to as an “applying step”). The method for manufacturing a semiconductor substrate further includes subjecting a coating film formed in the applying step to at least one process selected from the group consisting of radiation exposure and plasma exposure (hereinafter also referred to as a “processing step”). Through the processing step and, as necessary, the heating step (described later), a metal-containing film is formed. In addition, the method for manufacturing a semiconductor substrate preferably includes: forming a resist pattern directly or indirectly on the metal-containing film after the processing step (hereinafter also referred to as a “resist pattern forming step”); and forming a pattern on the film by etching using the resist pattern as a mask (hereinafter also referred to as an “etching step”).

If necessary, the method for manufacturing a semiconductor substrate may further include, before the resist pattern forming step, forming an organic underlayer film directly or indirectly on the substrate having a metal-containing film after the processing step (hereinafter also referred to as an “organic underlayer film forming step”).

If necessary, the method for manufacturing a semiconductor substrate may further include, before the resist pattern forming step, forming a silicon-containing film directly or indirectly on the substrate having a metal-containing film after the processing step (hereinafter also referred to as a “silicon-containing film forming step”).

First, a composition for film formation to be used in the method for manufacturing a semiconductor substrate is described. After that, description will be made to respective steps in the case where the method includes the resist pattern forming step and the etching step, which are preferable steps, and an organic underlayer film forming step and a silicon-containing film forming step, which are optional steps.

### <Composition for Film Formation>

The composition includes a compound [A], and a solvent [B]. The composition may further include other optional components as long as the effect of the present invention is not impaired.

### [Compound [A]]

The compound (A) is a compound composed of at least a metal atom and an organic acid. Examples of the metal atom constituting the compound [A] include metal atoms of Groups 3 to 16 of the periodic table (excluding silicon atom). The compound [A] may have one kind or two or more kinds of metal atom.

Examples of Group 3 metal atom include scandium, yttrium, lanthanum, and cerium;
examples of Group 4 metal atom include titanium, zirconium, and hafnium;
examples of Group 5 metal atom include vanadium, niobium, and tantalum;
examples of Group 6 metal atom include chromium, molybdenum, and tungsten;
examples of Group 7 metal atom include manganese and rhenium;
examples of Group 8 metal atom include iron, ruthenium, and osmium;
examples of Group 9 metal atom include cobalt, rhodium, and iridium;
examples of Group 10 metal atom include nickel, palladium, and platinum;
examples of Group 11 metal atom include copper, silver, and gold;
examples of Group 12 metal atom include zinc, cadmium, and mercury;
examples of Group 13 metal atom include aluminum, gallium, and indium;
examples of Group 14 metal atom include germanium, tin, and lead;
examples of Group 15 metal atom include antimony and bismuth; and
examples of Group 16 metal atom include tellurium.

As the metal atom constituting the compound [A], metal atoms of Group 3 to Group 16 are preferable, metal atoms of Group 4 to Group 14 are more preferable, metal atoms of Group 4, Group 5, and Group 14 are still more preferable, and metal atoms of Group 4 are particularly preferable. Specifically, titanium, zirconium, hafnium, tantalum, tungsten, tin, or a combination thereof is more preferable.

The compound [A] includes at least an organic acid (hereinafter also referred to as “organic acid [a]”) as a component other than the metal atom (hereinafter also referred to as “compound [x]”). Examples of the compound [x] other than the organic acid [a] include a hydroxy acid ester, a β-diketone, an α,α-dicarboxylic acid ester, and an amine compound. Herein, the “organic acid” refers to any organic compound that exhibits acidity, and the “organic compound” refers to any compound having at least one carbon atom.

Examples of the organic acid [a] include carboxylic acids, sulfonic acids, sulfinic acids, organic phosphinic acids, organic phosphonic acids, phenols, enols, thiols, acid imides, oximes, and sulfonamides.

Examples of the carboxylic acids include aliphatic carboxylic acids and aromatic carboxylic acids. Examples of the aliphatic carboxylic acids include monocarboxylic acids such as formic acid, acetic acid, propionic acid, butanoic acid (butyric acid), isobutyric acid, pentanoic acid, hexanoic acid, heptanoic acid, octanoic acid, nonanoic acid, decanoic acid, 2-ethylhexanoic acid, oleic acid, acrylic acid, methacrylic acid, trans-2,3-dimethylacrylic acid, stearic acid, linoleic acid, linolenic acid, arachidonic acid, salicylic acid, monochloroacetic acid, dichloroacetic acid, trichloroacetic acid, trifluoroacetic acid, and pentafluoropropionic acid; dicarboxylic acids such as oxalic acid, malonic acid, maleic acid, methylmalonic acid, fumaric acid, adipic acid, sebacic acid, and tartaric acid; and carboxylic acids having three or more carboxy groups such as citric acid.

The compound [A] may include a compound represented by the formula (1) (hereinafter also referred to as “compound [a1]”) as the aromatic carboxylic acid. Compounds whose carboxy group does not directly bond to an aromatic ring are also included in the aromatic carboxylic acids.

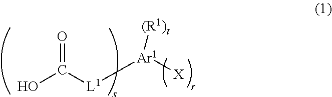

In the formula (1), R¹ is a hydroxy group, a nitro group, a halogen atom, or a monovalent organic group having 1 to 20 carbon atoms, provided that the monovalent organic group is different from a structure corresponding to -L¹-COOH) and a structure corresponding to X in the formula; Ar¹ is an r+s+t-valent aromatic ring structure having 5 to 30 carbon atoms; X is a crosslinkable group; L¹ is a single bond or a divalent linking group; t is an integer of 0 to 2, when t is 2, two R¹s are identical to or different from each other; r is an integer of 1 to 4, when r is 2 or more, a plurality of Xs are identical to or different from each other; and s is an integer of 1 to 4, and when s is 2 or more, a plurality of L¹s are identical to or different from each other.

Examples of the monovalent organic group having 1 to 20 carbon atoms represented by R¹ include a monovalent hydrocarbon group having 1 to 20 carbon atoms, a group having a divalent heteroatom-containing group between carbon and carbon of the hydrocarbon group (hereinafter also referred to as “group (α)”), a group obtained by replacing some or all of hydrogen atoms of the hydrocarbon group with a monovalent heteroatom-containing group (hereinafter also referred to as “group (β)”), and a group obtained by replacing some or all of hydrogen atoms of the group (α) with a monovalent heteroatom-containing group (hereinafter also referred to as “group (γ)”), or a combination thereof.

However, as the monovalent organic group having 1 to 20 carbon atoms represented by R¹, a structure corresponding to -L¹-COOH) and a structure corresponding to X in the formula (1) are excluded.

Examples of the monovalent hydrocarbon group having 1 to 20 carbon atoms include a monovalent chain hydrocarbon group having 1 to 20 carbon atoms, a monovalent alicyclic hydrocarbon group having 3 to 20 carbon atoms, a monovalent aromatic hydrocarbon group having 6 to 20 carbon atoms, and a group obtained by combining these groups.

Examples of the monovalent chain hydrocarbon group having 1 to 20 carbon atoms include alkyl groups such as a methyl group, an ethyl group, an n-propyl group, an i-propyl group, an n-butyl group, a sec-butyl group, and a tert-butyl group, alkenyl groups such as an ethenyl group, a propenyl group, and a butenyl group, and alkynyl groups such as an ethynyl group, a propynyl group, and a butynyl group.

Examples of the monovalent alicyclic hydrocarbon group having 3 to 20 carbon atoms include cycloalkyl groups such as a cyclopentyl group and a cyclohexyl group, cycloalkenyl groups such as a cyclopropenyl group, a cyclopentenyl group, and a cyclohexenyl group, bridged cyclic saturated hydrocarbon groups such as a norbornyl group, an adamantyl group, and a tricyclodecyl group, and bridged cyclic unsaturated hydrocarbon groups such as a norbornenyl group and a tricyclodecenyl group.

Examples of the monovalent aromatic hydrocarbon group having 6 to 20 carbon atoms include a phenyl group, a tolyl group, a naphthyl group, an anthracenyl group, and a pyrenyl group.

Examples of the hetero atom that constitutes the divalent or monovalent hetero atom-containing group include an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent heteroatom-containing group include —CO—, —CS—, —NR′—, —O—, —S—, and a group obtained by combining them. R′ is a hydrogen atom or a monovalent hydrocarbon group having 1 to 10 carbon atoms.

Examples of the monovalent heteroatom-containing group include a hydroxy group, a sulfanyl group, a cyano group, a nitro group, and a halogen atom.

R¹ is preferably a hydroxy group, an alkyl group having 1 to 5 carbon atoms, or a halogen atom, more preferably a hydroxy group, a methyl group, or a chlorine atom.

Examples of the r+s+t-valent aromatic ring structure having 5 to 30 carbon atoms represented by Ar¹ include a structure obtained by removing r+s+t hydrogen atoms from a structure having 5 to 30 carbon atoms including an aromatic ring. The structure having 5 to 30 carbon atoms and containing an aromatic ring is not limited to a structure containing only an aromatic ring, and includes a structure in which an aromatic ring and an alicyclic ring are combined. Examples of the structure in which an aromatic ring and an alicyclic ring are combined include a fused ring in which the aromatic ring and the alicyclic ring share one side (two adjacent atoms), and a ring assembly in which the aromatic ring and the alicyclic ring are bonded by a single bond.

The aromatic ring is preferably an aromatic ring having 5 to 30 carbon atoms, and examples thereof include aromatic hydrocarbon rings such as a benzene ring, a naphthalene ring, an anthracene ring, a phenalene ring, a phenanthrene ring, a pyrene ring, a fluorene ring, a perylene ring, and a coronene ring, aromatic heterocyclic rings such as a furan ring, a pyrrole ring, a thiophene ring, a phosphole ring, a pyrazole ring, an oxazole ring, an isoxazole ring, a thiazole ring, a pyridine ring, a pyrazine ring, a pyrimidine ring, a pyridazine ring, and a triazine ring, or a combination thereof (that is, a fused ring).

Examples of the alicyclic ring include an alicyclic hydrocarbon having 3 to 20 carbon atoms and an aliphatic heterocyclic ring having 3 to 20 carbon atoms.

As the alicyclic hydrocarbon having 3 to 20 carbon atoms, a structure corresponding to the monovalent alicyclic hydrocarbon group having 3 to 20 carbon atoms in R¹ can be suitably employed.

Examples of the aliphatic heterocyclic ring having 3 to 20 carbon atoms include:
oxygen atom-containing aliphatic heterocyclic rings such as oxirane, tetrahydrofuran, tetrahydropyran, dioxolane, and dioxane;
nitrogen atom-containing aliphatic heterocyclic rings such as aziridine, pyrrolidine, piperidine, and piperazine;
sulfur atom-containing aliphatic heterocyclic rings such as thietane, thiolane, and thiane;
aliphatic heterocyclic rings containing multiple types of heteroatoms such as morpholine, 1,2-oxathiolane, and 1,3-oxathiolane; or
a combination thereof.

The aromatic ring structure is preferably an aromatic hydrocarbon ring structure having 6 to 14 carbon atoms or an aromatic heterocyclic ring structure having 6 to 10 carbon atoms, more preferably an aromatic hydrocarbon ring structure having 6 to 14 carbon atoms, still more preferably a benzene ring, a naphthalene ring, an anthracene ring, or a phenanthrene ring, particularly preferably a benzene ring.

The crosslinkable group represented by X is a group containing a structure having crosslinkability. The structure having crosslinkability is not particularly limited as long as the structure is a structure configured to form a crosslinked structure between molecules through a reaction under a heating condition, an active energy ray irradiation condition, an acidic condition, or the like. Examples of the structure having crosslinkability include a structure containing a carbon-carbon double bond, a structure containing a carbon-carbon triple bond, an epoxy group, an oxetanyl group, a halogen atom, an acid anhydride structure, a carboxy group, an amino group, a cyano group, and a hydroxy group.

X is preferably a group selected from the group consisting of groups represented by any of the formulas (2-1) to (2-5).

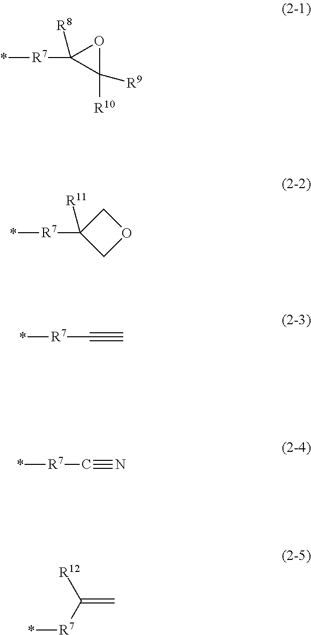

In the formulas (2-1), (2-2), and (2-5), R⁸, R⁹, R¹⁰, R¹¹, and R¹² are each independently a hydrogen atom or a monovalent organic group having 1 to 20 carbon atoms.

In the formulas (2-1) to (2-5), R⁷s are each independently a divalent linking group or a single bond. * is a bond to an atom constituting Ar¹.

As the monovalent organic group having 1 to 20 carbon atoms represented by R⁸, R⁹, R¹⁰, R¹¹, and R¹², a monovalent organic group having 1 to 20 carbon atoms represented by R¹ of the formula (1) can be suitably employed.

R⁸, R⁹, R¹⁰, and R¹¹ are preferably a hydrogen atom. R¹² is preferably a hydrogen atom or a methyl group.

As the divalent linking group represented by R⁷, for example, a divalent hydrocarbon group, —COO—, —OCO—, —O—CO—O—, —CONH—, —O—, —S—, —CO—, or a group obtained by combining these groups can be suitably employed.

As the divalent hydrocarbon group in R⁷, a group obtained by removing one hydrogen atom from the monovalent hydrocarbon group having 1 to 20 carbon atoms in R¹ can be suitably employed.

R⁷ is preferably a divalent chain hydrocarbon group having 1 to 5 carbon atoms, —O—, a combination thereof, or a single bond, more preferably a methylene group, —O—, a combination of a methylene group and —O—, or a single bond.

As the divalent linking group represented by L¹, a divalent linking group represented by R⁷ can be suitably employed.

L¹ is preferably a divalent chain hydrocarbon group having 1 to 5 carbon atoms or a single bond, more preferably a methylene group, an ethanediyl group, a propane-2,2-diyl group, or a single bond.

t is preferably 0 or 1. r is preferably an integer of 1 to 3, more preferably 1 or 2. s is preferably an integer of 1 to 3, more preferably 1 or 2.

Specific examples of the compound [a1] include compounds represented by the formulas (1-1) to (1-30).

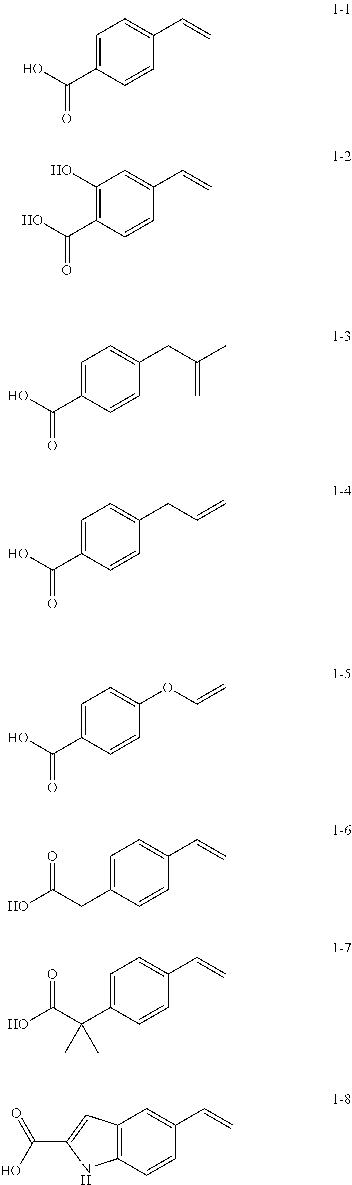

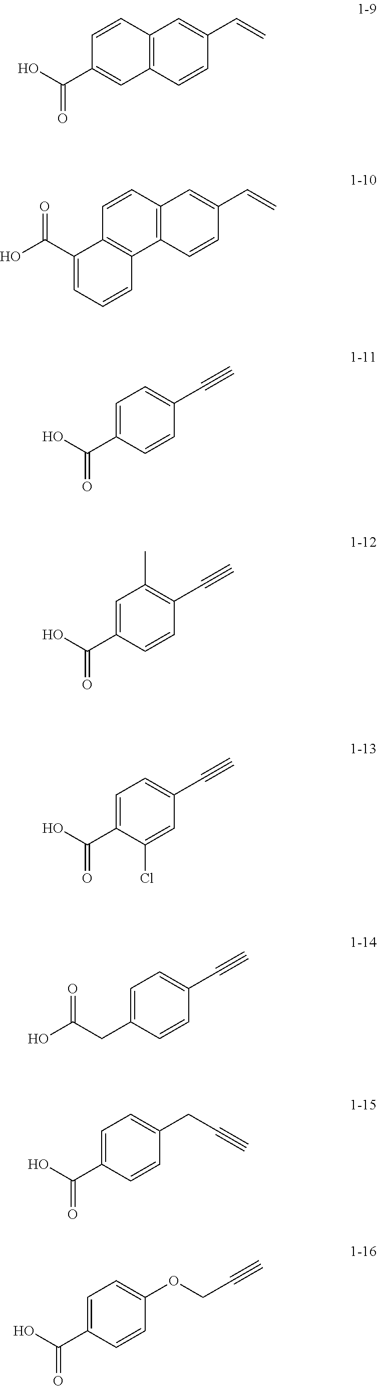

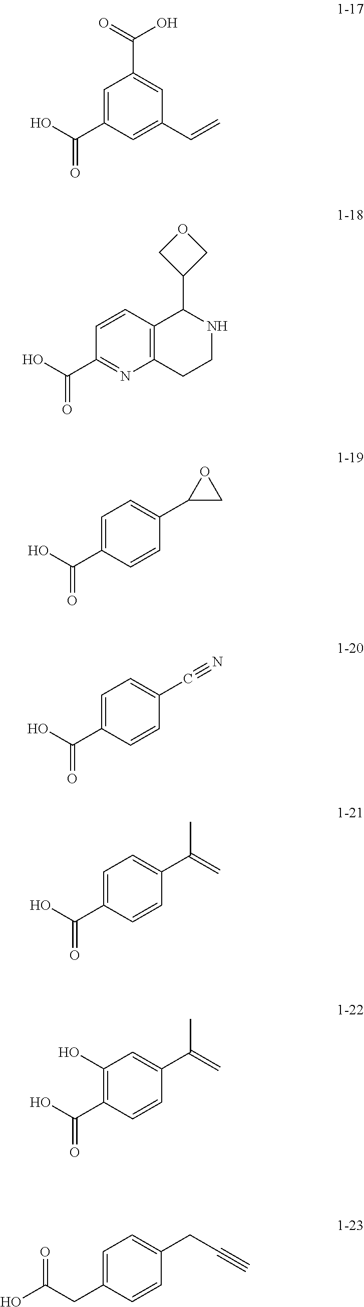

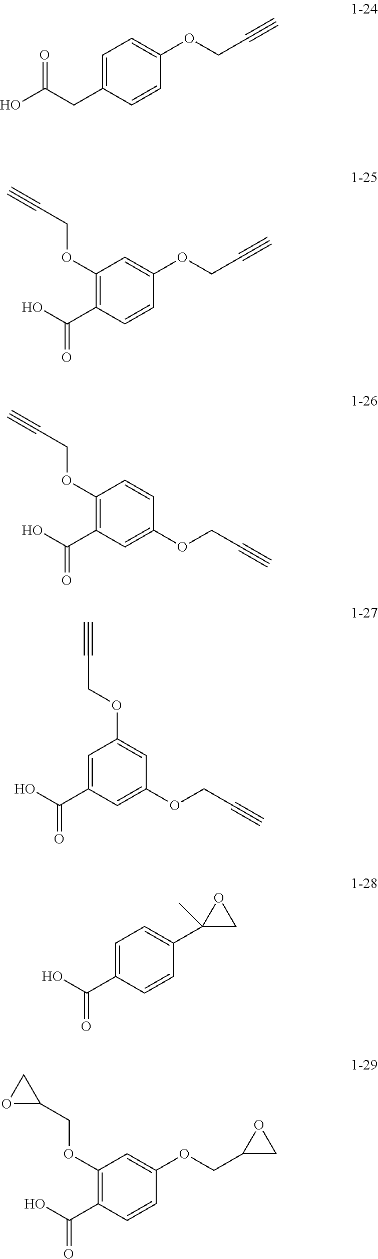

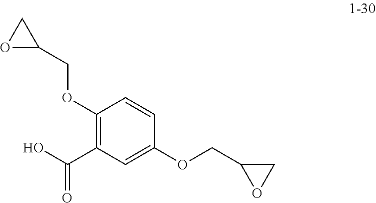 [SMILES: O=C(O)c1cc(OCC2CO2)ccc1OCC1CO1]

Examples of aromatic carboxylic acids other than the compound [a1] include benzoic acid, p-aminobenzoic acid, gallic acid, shikimic acid, and phthalic acid.

Examples of the sulfonic acids include benzenesulfonic acid and p-toluenesulfonic acid.

Examples of the sulfinic acids include benzenesulfinic acid and p-toluenesulfinic acid.

Examples of the organic phosphinic acids include diethylphosphinic acid, methylphenylphosphinic acid, and diphenylphosphinic acid.

Examples of the organic phosphonic acids include methylphosphonic acid, ethylphosphonic acid, t-butylphosphonic acid, cyclohexylphosphonic acid, and phenylphosphonic acid.

Examples of the phenols include monohydric phenols such as phenol, cresol, 2,6-xylenol, and naphthol;
dihydric phenols such as catechol, resorcinol, hydroquinone, and 1,2-naphthalenediol; and
trihydric or higher phenols such as pyrogallol and 2,3,6-naphthalenetriol.

Examples of the enols include 2-hydroxy-3-methyl-2-butene and 3-hydroxy-4-methyl-3-hexene.

Examples of the thiols include mercaptoethanol and mercaptopropanol.

Examples of the acid imides include carboxylic acid imides such as maleimide and succinimide, and sulfonic acid imides such as di(trifluoromethanesulfonic acid) imide and di(pentafluoroethanesulfonic acid) imide.

Examples of the oximes include aldoximes such as benzaldoxime and salicylaldoxime, and ketoximes such as diethylketoxime, methylethylketoxime, and cyclohexanone oxime.

Examples of the sulfonamides include methylsulfonamide, ethylsulfonamide, benzenesulfonamide, and toluenesulfonamide.

The organic acid [a] is preferably a carboxylic acid, more preferably a monocarboxylic acid, still more preferably a monocarboxylic acid having 3 to 8 carbon atoms, and particularly preferably propionic acid, butyric acid, isobutyric acid, methacrylic acid, 4-vinylbenzoic acid, 4-ethynylbenzoic acid, or 2-ethylhexanoic acid.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the amine compounds include diethanolamine and triethanolamine.

As the compound [A], a metal compound composed of a metal atom of Group 4, Group 5, or Group 14 and the compound [a1] is preferable, a metal compound composed of a metal atom of Group 4 or Group 14 and the compound [a1] having a crosslinkable group represented by the formula (2-3) or (2-5) is more preferable, and a metal compound composed of titanium, zirconium, hafnium, tantalum, tungsten, or tin and 4-vinylbenzoic acid, 4-ethynylbenzoic acid or 4-vinylbenzeneacetic acid is still more preferable. The contained form of the organic acid [a] in the compound [A] also includes an organic acid anion obtained by removing a hydrogen ion from the organic acid [a].

The compound [A] may include one or two or more of the metal compound.

The compound [A] may include one or two or more of the organic acid [a].

The lower limit of the content ratio of the compound [A] accounting for in all components contained in the composition is preferably 0.1% by mass, more preferably 0.5% by mass, and still more preferably 1% by mass. The upper limit of the content ratio is preferably 20% by mass, more preferably 14% by mass, and still more preferably 8% by mass.

### [Method for Synthesizing Compound [A]]

The compound [A] can be synthesized by, for example, a method of performing a hydrolysis-condensation reaction using a metal-containing compound (hereinafter also referred to as “metal-containing compound [b]”), a method of performing a ligand substitution reaction using a metal-containing compound [b], or the like. Herein, the “hydrolysis-condensation reaction” refers to a reaction in which the hydrolyzable group of the metal-containing compound [b] is hydrolyzed to be converted into-OH, and the resulting two-OH groups are dehydration-condensed to form —O—.

(Metal-Containing Compound [b])

The metal-containing compound [b] is a metal compound precursor (b1) having a hydrolyzable group, a hydrolysate of a metal compound precursor (b1) having a hydrolyzable group, a hydrolysis-condensate of a metal compound precursor (b1) having a hydrolyzable group, or a combination thereof. The metal compound precursor (b1) may be used singly or two or more thereof may be used in combination.

Examples of the hydrolyzable group include a halogen atom, an alkoxy group, and an acyloxy group.

Examples of the halogen atom include a fluorine atom, a chlorine atom, a bromine atom, and an iodine atom.

Examples of the alkoxy group include a methoxy group, an ethoxy group, a n-propoxy group, an isopropoxy group, and a n-butoxy group.

Examples of the acyloxy group include an acetoxy group, a propionyloxy group, a butyryloxy group, a pivaloyloxy group, a t-amylcarbonyloxy group, an n-hexanecarbonyloxy group, and an n-octanecarbonyloxy group.

As the hydrolyzable group, an alkoxy group and an acyloxy group are preferable, and an isopropoxy group and an acetoxy group are more preferable.

When the metal-containing compound [b] is a hydrolysis-condensate of a metal compound precursor (b1), the hydrolysis-condensate of the metal compound precursor (b1) may be a hydrolysis-condensate of the metal compound precursor (b1) having a hydrolyzable group and a compound containing a metalloid atom as long as the effect of the present invention is not impaired. That is, the hydrolysis-condensate of the metal compound precursor (b1) may contain a metalloid atom as long as the effect of the present invention is not impaired. Examples of the metalloid atom include silicon, boron, germanium, antimony, and tellurium. The content of the metalloid atom in the hydrolysis-condensate of the metal compound precursor (b1) is usually less than 50 atom % based on the total of the metal atom and the metalloid atom in the hydrolysis-condensate. The upper limit of the content of the metalloid atom is preferably 30 atom %, more preferably 10 atom based on the total of the metal atom and the metalloid atom in the hydrolysis-condensate.

Examples of the metal compound precursor (b1) include a compound represented by formula (α) (hereinafter also referred to as “compound [m]”).

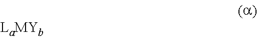

In the formula (α), M is a metal atom. L is a ligand. a is an integer of 0 to 4. When a is 2 or more, a plurality of L's are the same or different. Y is a hydrolyzable group selected from among a halogen atom, an alkoxy group, and an acyloxy group. b is an integer of 2 to 6. The plurality of Y's may be the same or different. Note that a+b is 4 or more, and L is a ligand that does not correspond to Y.

Examples of the metal atom represented by M include metal atoms the same as those disclosed as examples of the metal atom constituting the compound [A].

Examples of the ligand represented by L include a monodentate ligand and a multidentate ligand.

Examples of the monodentate ligand include a hydroxo ligand, a carboxy ligand, an amide ligand, and ammonia.

Examples of the amide ligand include an unsubstituted amide ligand (NH₂), a methylamide ligand (NHMe), a dimethylamide ligand (NMe₂), a diethylamide ligand (NEt₂), and a dipropylamide ligand (NPr₂).

Examples of the multidentate ligand include hydroxy acid esters, β-diketones, β-ketoesters, β-dicarboxylic acid esters, hydrocarbons having a π bond, and diphosphines.

Examples of the hydroxy acid esters include glycolic acid esters, lactic acid esters, 2-hydroxycyclohexane-1-carboxylic acid esters, and salicylic acid esters.

Examples of the β-diketones include 2,4-pentanedione, 3-methyl-2,4-pentanedione, and 3-ethyl-2,4-pentanedione.

Examples of the β-ketoesters include acetoacetic acid esters, α-alkyl-substituted acetoacetic acid esters, β-ketopentanoic acid esters, benzoylacetic acid esters, and 1,3-acetonedicarboxylic acid esters.

Examples of the β-dicarboxylic acid esters include malonic diesters, α-alkyl-substituted malonic diesters, α-cycloalkyl-substituted malonic diesters, and α-aryl-substituted malonic diesters.

Examples of the hydrocarbons having a n bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphines include 1,1-bis(diphenylphosphino) methane, 1,2-bis(diphenylphosphino) ethane, 1,3-bis(diphenylphosphino) propane, 2,2′-bis(diphenylphosphino)-1,1′-binaphthyl, and 1,1′-bis(diphenylphosphino) ferrocene.

Examples of the halogen atom represented by Y include a fluorine atom, a chlorine atom, a bromine atom, and an iodine atom.

Examples of the alkoxy group represented by Y include a methoxy group, an ethoxy group, a propoxy group, and a butoxy group.

Examples of the acyloxy group represented by Y include an acetoxy group, a butyryloxy group, a pivaloyloxy group, a t-amylcarbonyloxy group, an n-hexanecarbonyloxy group, and an n-octanecarbonyloxy group.

As Y, an alkoxy group and an acyloxy group are preferable, and an isopropoxy group and an acetoxy group are more preferable.

As b, 3 and 4 are preferable, and 4 is more preferable.

As the metal-containing compound [b], metal alkoxides subjected to neither hydrolysis nor hydrolysis-condensation and metal acyloxides subjected to neither hydrolysis nor hydrolysis-condensation are preferable.

Examples of the metal-containing compound [b] include zirconium tetra-n-butoxide, zirconium tetra-n-propoxide, zirconium tetraisopropoxide, hafnium tetraethoxide, indium triisopropoxide, hafnium tetraisopropoxide, hafnium tetra-n-propoxide, hafnium tetra-n-butoxide, tantalum pentaethoxide, tantalum penta-n-butoxide, tungsten pentamethoxide, tungsten pentaethoxide, tungsten penta-n-butoxide, tungsten hexaethoxide, tungsten hexa-n-butoxide, iron chloride, zinc diisopropoxide, zinc acetate dihydrate, tetrabutyl orthotitanate, titanium tetra-n-butoxide, titanium tetra-n-propoxide, titanium tetraisopropoxide, zirconium di-n-butoxide bis(2,4-pentanedionate), titanium tri-n-butoxide stearate, bis(cyclopentadienyl) hafnium dichloride, bis(cyclopentadienyl) tungsten dichloride, diacetato[(S)-(−)-2,2′-bis(diphenylphosphino)-1,1′-binaphthyl]ruthenium, dichloro[ethylenebis(diphenylphosphine)]cobalt, titanium butoxide oligomer, aminopropyltrimethoxytitanium, aminopropyltriethoxyzirconium, 2-(3,4-epoxycyclohexyl)ethyltrimethoxyzirconium, γ-glycidoxypropyltrimethoxyzirconium, 3-isocyanopropyltrimethoxyzirconium, 3-isocyanopropyltriethoxyzirconium, triethoxymono(acetylacetonato)titanium, tri-n-propoxymono(acetylacetonato)titanium, tri-isopropoxymono(acetylacetonato)titanium, triethoxymono(acetylacetonato)zirconium, tri-n-propoxymono(acetylacetonato)zirconium, tri-isopropoxymono(acetylacetonato)zirconium, diisopropoxybis(acetylacetonato)titanium, di-n-butoxybis(acetylacetonato)titanium, di-n-butoxybis(acetylacetonato)zirconium, tri(3-methacryloxypropyl)methoxyzirconium, tri(3-acryloxypropyl)methoxyzirconium, tin tetramethoxide, tin tetraethoxide, tin tetra-n-propoxide, tin tetraisopropoxide, tin tetra-n-butoxide, tin tetraisobutoxide, tin tetra-sec-butoxide, tin tetra-tert-butoxide, lanthanum oxide, and yttrium oxide.

Among them, metal alkoxides and metal acyloxides are preferable, metal alkoxides are more preferable, and alkoxides of titanium, zirconium, hafnium, tantalum, tungsten, and tin are still more preferable.

The lower limit of the use amount of the organic acid [a] required for the synthesis of the compound [A] (the total amount when the organic acid [a] other than the compound [a1] is contained) is preferably 1 mol, more preferably 2 mol, with respect to 1 mol of the metal-containing compound [b]. On the other hand, the upper limit of the use amount of the organic acid [a] is preferably 6 mol, more preferably 5 mol, with respect to 1 mole of the metal-containing compound [b].

In the synthesis reaction of the compound [A], in addition to the metal compound precursor (b1) and the compound [a1], a compound capable of serving as a multidentate ligand represented by L in the compound of the formula (α), a compound capable of serving as a bridging ligand, or the like may be added. Examples of the compound capable of serving as a bridging ligand include compounds having a plurality of hydroxy groups, isocyanate groups, amino groups, ester groups, or amide groups.

Examples of the method of performing the hydrolysis-condensation reaction using the metal-containing compound [b] include a method of subjecting the metal-containing compound [b] to a hydrolysis-condensation reaction in a solvent containing water. In this case, another compound having a hydrolyzable group may be added, as necessary. The lower limit of the amount of water used in the hydrolysis-condensation reaction is preferably 0.2 times mol, more preferably 1 time mol, and still more preferably 3 times mol, in the number of moles, based on the hydrolyzable group of the metal-containing compound [b] and the like. The upper limit of the amount of water is preferably 20 times mol, more preferably 15 times mol, and still more preferably 10 times mol.

Examples of the method of performing the ligand substitution reaction using the metal-containing compound [b] include a method involving mixing the metal-containing compound [b] and the compound [a1]. In this case, the metal-containing compound [b] and the compound [a1] may be mixed in a solvent, or may be mixed without using a solvent. In the mixing, a base such as triethylamine may be added, as necessary. The addition amount of the base is, for example, 1 part by mass or more and 200 parts by mass or less based on 100 parts by mass of the total use amount of the metal-containing compound [b] and the organic acid [a].

The solvent to be used in the synthesis reaction of the compound [A] (hereinafter also referred to as “solvent [d]”) is not particularly limited, and for example, the same solvents as those disclosed as examples of the solvent [B] described later can be used. Among them, alcohol-based solvents, ether-based solvents, ester-based solvents, and hydrocarbon-based solvents are preferable, alcohol-based solvents, ether-based solvents, and ester-based solvents are more preferable, monoalcohol-based solvents, polyhydric alcohol partial ether-based solvents, and polyhydric alcohol partial ether carboxylate-based solvents are still more preferable, and monoalcohol-based solvents having 1 to 4 carbon atoms propylene glycol monoethyl ether, and propylene glycol monomethyl ether acetate are particularly preferable.

When the solvent [d] is used in the synthesis reaction of the compound [A], the solvent used may be removed after the reaction, but may be used as it is as the solvent [B] of the composition for forming a film without being removed after the reaction.

### [Solvent [B]]

The solvent [B] is not particularly limited as long as the solvent [B] is a solvent capable of dissolving or dispersing at least the compound [A], other optional components, and the like. The composition may contain one or two or more types of the solvent [B].

Examples of the solvent [B] include organic solvents. Examples of the organic solvent include alcohol-based solvents, ketone-based solvents, ether-based solvents, ester-based solvents, nitrogen-containing solvents, and sulfur-containing solvents.

Examples of the alcohol-based solvents include monoalcohol-based solvents such as methanol, ethanol, n-propanol, and 4-methyl-2-pentanol, and polyhydric alcohol-based solvents such as ethylene glycol, 1,2-propylene glycol, triethylene glycol, and tripropylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the ether-based solvents include chain ether-based solvents such as n-butyl ether; polyhydric alcohol ether-based solvents such as cyclic ether-based solvents such as tetrahydrofuran and 1,4-dioxane; and polyhydric alcohol partial ether-based solvents such as propylene glycol monoethyl ether, tripropylene glycol monomethyl ether, and tetraethylene glycol monomethyl ether.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the nitrogen-containing solvents include chain nitrogen-containing solvents such as N, N-dimethylacetamide, and cyclic nitrogen-containing solvents such as N-methylpyrrolidone.

Examples of the sulfur-containing solvents include chain sulfur-containing solvents such as dimethylsulfone and dimethylsulfoxide, and cyclic sulfur-containing solvents such as sulfolane.

Other examples include aromatic solvents such as toluene, xylene, and mesitylene.

As the solvent [B], an alcohol-based solvent, an ether-based solvent, an ester-based solvent, a ketone-based solvent, or a combination thereof is preferable, a monoalcohol-based solvent, a polyhydric alcohol partial ether-based solvent, an acetic acid monoester-based solvent, a polyhydric alcohol partial ether carboxylate-based solvent, a chain ketone-based solvent, or a combination thereof is more preferable, and 4-methyl-2-pentanol, propylene glycol monomethyl ether, butyl acetate, propylene glycol monomethyl ether acetate, 2-heptanone, or a combination thereof is still more preferable.

The lower limit of the content of the solvent [B] to the total amount of the compound [A] and the solvent [B] is preferably 50% by mass, more preferably 60% by mass, still more preferably 70% by mass. The upper limit of the content is preferably 99.9% by mass, more preferably 99.5% by mass, still more preferably 99% by mass. When the content of the solvent [B] is adjusted within the above range, the preparation of the composition can be facilitated, and the coatability can be improved.

### [Other Optional Components]

The composition may contain, for example, an aromatic ring-containing compound having a molecular weight of 300 or more, an acid generating agent, a macromolecular additive, a polymerization inhibitor, a surfactant, a crosslinking agent, a basic compound etc. as components other than those described above.

When the composition contains other optional components, the content of the other optional components in the composition can be appropriately determined according to the type, function, and so on of the other optional components to be used.

The aromatic ring-containing compound having a molecular weight of 300 or more is not particularly limited as long as the compound is a compound having an aromatic ring and a molecular weight of 300 or more. The aromatic ring-containing compound may be a polymer having two or more structural units (repeating units) containing an aromatic ring, or otherwise. Examples of the aromatic ring-containing compound include compounds described in paragraphs [0163] to [0168] of WO2023/021971, polymers described in paragraphs [0221] to [0225] of JP-W-2022-521531, and polymers described in paragraph [0067] of JP-W-2023-521230.

The acid generating agent is a compound that generates an acid by radiation irradiation and/or heating. The composition may contain one or two or more of the acid generating agent.

Examples of the acid generating agent include an onium salt compound and an N-sulfonyloxyimide compound.

When the composition contains a macromolecular additive, the composition can further enhance the coatability to a substrate and an organic underlayer film and the continuity of a film. The composition may contain one or two or more of the macromolecular additive.

Examples of the macromolecular additive include (poly)oxyalkylene-based macromolecular compounds, fluorine-containing macromolecular compounds, and non-fluorine-containing macromolecular compounds.

Examples of the (poly)oxyalkylene-based macromolecular compounds include: polyoxyalkylenes such as a (poly)oxyethylene-(poly)oxypropylene adduct; (poly)oxyalkyl ethers such as diethylene glycol heptyl ether, polyoxyethylene oleyl ether, polyoxypropylene butyl ether, polyoxyethylene polyoxypropylene-2-ethyl hexyl ether, and an adduct of oxyethylene-oxypropylene to a higher alcohol having 12 to 14 carbon atoms; (poly)oxyalkylene (alkyl) aryl ethers such as polyoxypropylene phenyl ether and polyoxyethylene nonyl phenyl ether; acetylene ethers obtained by addition polymerization of acetylene alcohol and an alkylene oxide, such as 2,4,7,9-tetramethyl-5-decyne-4,7-diol, 2,5-dimethyl-3-hexyne-2,5-diol, and 3-methyl-1-butyn-3-ol; (poly)oxyalkylene fatty acid esters such as diethylene glycol oleic acid ester, diethylene glycol lauric acid ester, and ethylene glycol distearic acid ester; (poly)oxyalkylene sorbitan fatty acid esters such as polyoxyethylene sorbitan monolauric acid ester and polyoxyethylene sorbitan trioleic acid ester; (poly)oxyalkylene alkyl (aryl) ether sulfuric acid ester salts such as polyoxypropylene methyl ether sodium sulfate and polyoxyethylene dodecyl phenol ether sodium sulfate; (poly)oxyalkylene alkyl phosphoric acid esters such as (poly)oxyethylene stearyl phosphoric acid ester; and (poly)oxyalkylene alkyl amines such as polyoxyethylene lauryl amine.

Examples of the fluorine-containing macromolecular compounds include compounds disclosed in JP-A-2011-89090. Examples of the fluorine-containing macromolecular compounds include compounds containing a repeating unit derived from a (meth)arylate compound having a fluorine atom and a repeating unit derived from a (meth)acrylate compound having two or more (preferably five or more) alkyleneoxy groups (preferably an ethyleneoxy group, a propyleneoxy group).

Examples of the non-fluorine-containing macromolecular compounds include compounds containing one kind or two or more kinds of repeating units derived from a (meth)acrylate monomer such as a linear or branched alkyl (meth)acrylate such as lauryl (meth)acrylate, 2-ethylhexyl (meth)acrylate, n-butyl (meth)acrylate, t-butyl (meth)acrylate, isooctyl (meth)acrylate, isostearyl (meth)acrylate, or isononyl (meth)acrylate, an alkoxyethyl (meth)acrylate such as methoxyethyl (meth)acrylate, an alkylene glycol di(meth)acrylate such as ethylene glycol di(meth)acrylate or 1,3-butylene glycol di(meth)acrylate, a hydroxyalkyl (meth)acrylate such as 2-hydroxyethyl (meth)acrylate, 2-hydroxypropyl (meth)acrylate, 2-hydroxybutyl (meth)acrylate, or 4-hydroxybutyl (meth)acrylate, dicyclopentenyloxyethyl (meth)acrylate, or nonylphenoxy polyethylene glycol (having a —(CH₂CH₂O)ₙ— structure, n=1 to 17) (meth)acrylate.

When the composition contains a polymerization inhibitor, the storage stability of the composition can be enhanced. The composition may contain one or two or more of the polymerization inhibitor.

Examples of the polymerization inhibitor include hydroquinone compounds such as 4-methoxyphenol and 2,5-di-tert-butylhydroquinone, and nitroso compounds such as N-nitrosophenylhydroxylamine and aluminum salts thereof.

When the composition contains a surfactant, the coatability to a substrate or an organic underlayer film and the continuity of a film can be further enhanced. The composition may contain one or two or more of the surfactant.

Examples of a commercially-available product of the surfactant include “Newcol 2320”, “Newcol 714-F”, “Newcol 723”, “Newcol 2307”, and “Newcol 2303” (which are all manufactured by NIPPON NYUKAZAI CO., LTD.), “Pionin D-1107-S”, “Pionin D-1007”, “Pionin D-1106-DIR”, “Newkalgen TG310”, “Pionin D-6105-W”, “Pionin D-6112”, and “Pionin D-6512” (which are all manufactured by TAKEMOTO OIL & FAT Co., Ltd.), “SURFYNOL 420” “SURFYNOL 440”, “SURFYNOL 465”, and “SURFYNOL 2502” (which are all manufactured by Air Products and Chemicals, Inc.), “MEGAFACE F171”, “MEGAFACE F172”, “MEGAFACE F173”, “MEGAFACE F176”, “MEGAFACE F177”, “MEGAFACE F141”, “MEGAFACE F142”, “MEGAFACE F143”, “MEGAFACE F144”, “MEGAFACE R30”, “MEGAFACE F437”, “MEGAFACE F475”, “MEGAFACE F479”, “MEGAFACE F482”, “MEGAFACE F562”, “MEGAFACE F563”, “MEGAFACE F780”, “MEGAFACE R-40”, “MEGAFACE DS-21”, “MEGAFACE RS-56”, “MEGAFACE RS-90”, and “MEGAFACE RS-72-K” (which are all manufactured by DIC Corporation), “Fluorad FC430” and “Fluorad FC431” (which are all manufactured by Sumitomo 3M Limited), “AsahiGuard AG710”, “Surflon S-382”, “Surflon SC-101”, “Surflon SC-102”, “Surflon SC-103”, “Surflon SC-104”, “Surflon SC-105”, and “Surflon SC-106 (which are all manufactured by AGC Inc.), and “FTX-218” and “NBX-15” (manufactured by NEOS Co., Ltd.).

The type of the crosslinking agent is not particularly limited, and a known crosslinking agent (provided that compounds corresponding to the aromatic ring-containing compound having a molecular weight of 300 or more are excluded) can be arbitrarily selected for use. Preferably, at least one selected from polyfunctional (meth)acrylates, cyclic ether-containing compounds, glycolurils, diisocyanates, melamines, benzoguanamines, polyfunctional thiol compounds, polysulfide compounds, and sulfide compounds is preferably used as the crosslinking agent. When the composition contains a crosslinking agent, the etching resistance of the resist lower layer film can be improved.

The basic compound promotes a curing reaction of the composition, and as a result, enhances the strength and the like of a film to be formed. Examples of the basic compound include a compound having a basic amino group, and a base generator that generates a compound having a basic amino group by the action of acid or the action of heat. Examples of the compound having a basic amino group include amine compounds. Examples of the base generator include an amide group-containing compound, a urea compound, and a nitrogen-containing heterocyclic compound. Examples of the amine compound, the amide group-containing compound, the urea compound, and the nitrogen-containing heterocyclic compound include compounds described in paragraphs to of JP-A-2016-27370.

As the defoaming agent, publicly known defoaming agents and the like can be used, and examples thereof include an alcohol defoaming agent, a phosphate ester defoaming agent, a fatty acid ester defoaming agent, a polyether defoaming agent, and a silicone defoaming agent. Examples of the fatty acid ester defoaming agent include methyl laurate, methyl palmitate, methyl stearate, propyl butyrate, butyl butyrate, ethyl isovalerate, and isobutyl propionate, and propyl butyrate and butyl butyrate are preferable. As the defoaming agent, a ketone-based solvent such as 2-heptanone may be used.

### [Method for Preparing Composition for Film Formation]

The composition for film formation can be prepared by mixing the compound [A], the solvent [B] and, as necessary, an optional component in a prescribed ratio and preferably filtering the resulting mixture through a membrane filter having a pore size of 0.5 μm or less, or the like. In the composition, the compound [A] is preferably dissolved in the solvent [B].

### [Applying Step]

In the applying step, the composition for film formation is applied to a substrate. The method of the application of the composition for film formation is not particularly limited, and the application can be performed by an appropriate method such as spin coating, cast coating, or roll coating. As a result, a coating film is formed, and volatilization of the solvent [B] or the like occurs, so that a film (a metal hardmask) as a resist underlayer film is formed.

Examples of the substrate include metal or metalloid substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferred. The substrate may be a substrate having a silicon nitride film, an alumina film, a silicon dioxide film, a tantalum nitride film, or a titanium nitride film formed thereon.

The substrate may have a pattern. Since the composition for film formation is superior in embeddability, where the composition for film formation is embedded in the substrate having a pattern, even when the substrate has a pattern, a good film can be formed while the gap between patterns is filled. Examples of the shape of the pattern include a trench pattern, a line-and-space pattern, a hole pattern, and a pillar pattern. Examples of the trench pattern and the line-and-space pattern include a pattern including a recess having a width of 1 nm or more and 100 nm or less, 50 nm or less, 30 nm or less, 20 nm or less, 15 nm or less, 10 nm or less, or 5 nm or less and a pattern including a recess having a depth of 5 nm or more and 1000 nm or less, or 500 nm or less. Examples of the hole pattern include a pattern including a hole having a diameter of 1 nm or more and 100 nm or less, 50 nm or less, 30 nm or less, 20 nm or less, 15 nm or less, 10 nm or less, or 5 nm or less and a pattern including a hole having a depth of 5 nm or more and 1000 nm or less, or 500 nm or less. Examples of the pillar pattern include a pattern including pillars having a width of 5 nm or more and 100 nm or less and a pattern including pillars having a height of 5 nm or more and 500 nm or less.

The lower limit of the average thickness of the resist underlayer film to be formed is preferably 3 nm, more preferably 5 nm, and still more preferably 10 nm. The upper limit of the average thickness is preferably 500 nm, more preferably 200 nm, and even more preferably 100 nm. The average thickness is measured as described in Examples.

### [Processing Step]

The method for manufacturing a semiconductor substrate includes subjecting a coating film formed in the applying step to at least one process selected from the group consisting of radiation exposure and plasma exposure. In the step, among these processes, only one process may be performed, or two or more processes may be performed sequentially or in parallel.

By subjecting the coating film to at least one process selected from the group consisting of radiation exposure and plasma exposure, volatilization of the solvent is promoted, and embeddability can be improved.

Hereinbelow, each of the processes will be described.

### (Radiation Exposure)

Examples of the radiation include electromagnetic rays such as visible rays (wavelength: more than 400 nm and 780 nm or less), ultraviolet rays (wavelength: 10 nm or more and 400 nm or less), and X rays (0.001 nm to 10 nm) and corpuscular rays such as electron rays and molecular rays. Among them, for example, electromagnetic rays or electron rays are preferred, and ultraviolet rays or electron rays are more preferred. The lower limit of the wavelength of the ultraviolet rays is, for example, preferably 13 nm, and more preferably 150 nm. The upper limit of the wavelength is, for example, preferably 370 nm, and more preferably 255 nm.

Examples of the method for exposure to ultraviolet rays include a method of using an irradiation light source such as a Xe excimer lamp (center emission wavelength: 172 nm) and a low pressure mercury lamp (center emission wavelength: 185 nm, 254 nm).

The lower limit of the exposure intensity of the ultraviolet rays from the Xe excimer lamp or the low pressure mercury lamp is, for example, preferably 1 mW/cm², and more preferably 5 mW/cm². The upper limit of the exposure intensity is, for example, preferably 300 mW/cm², and more preferably 200 mW/cm². The lower limit of the exposure amount of the extreme ultraviolet is, for example, preferably 5 mJ/cm², and more preferably 10 mJ/cm². The upper limit of the exposure amount is, for example, preferably 500 mJ/cm², and more preferably 400 mJ/cm². The lower limit of the exposure amount of the electron rays is, for example, preferably 20 μC/cm², and more preferably 40 μC/cm². The upper limit of the exposure amount is, for example, preferably 1,000 μC/cm², and more preferably 800 μC/cm².

The lower limit of the time of radiation exposure is, for example, preferably 10 seconds, more preferably 20 seconds, and still more preferably 30 seconds. The upper limit of the time is, for example, preferably 30 minutes, more preferably 20 minutes, and still more preferably 10 minutes.

The irradiation amount of the radiation is usually calculated by the exposure intensity and the exposure time, and is preferably, for example, 10 mJ to 5000 mJ, and may be 50 mJ to 4000 mJ, or 100 mJ to 3000 mJ.

The atmosphere in the radiation exposure is not particularly limited, and may be air, an inert gas such as nitrogen, or a reactive gas such as ozone or ammonia.

### (Plasma Exposure)

In the present disclosure, the “plasma” refers to those obtained by converting various gases into plasma.

Examples of the plasma include oxygen plasma, ozone plasma, nitrogen plasma, hydrogen plasma, chlorine plasma, helium plasma, neon plasma, argon plasma, krypton plasma, xenon plasma, and ammonia plasma. Among them, oxygen plasma, ozone plasma, helium plasma, or argon plasma is preferred, and oxygen plasma, helium plasma, or argon plasma is more preferred.

Examples of the method for exposure to plasma include the direct method, in which a substrate on which an IDT electrode is formed is placed in each gas atmosphere and plasma discharge is performed. As the plasma exposure conditions, usually, the gas flow rate is 50 cc/min or more and 100 cc/min or less, and the supply power is 100 W or more and 1,500 W or less.

The lower limit of the time of plasma exposure is, for example, preferably 10 seconds, more preferably 30 seconds, and still more preferably 1 minute. The upper limit of the time is, for example, preferably 10 minutes, more preferably 5 minutes, and still more preferably 2 minutes.

The method for manufacturing a semiconductor substrate preferably further includes heating a coating film formed in the applying step (hereinafter also referred to as a “heating step”). The curing of the coating film is promoted by heating the coating film. More specifically, volatilization or the like of the solvent [B] is promoted by heating the coating film.

The heating of the coating film is usually performed in the atmosphere but may be performed in a nitrogen atmosphere. The lower limit of the temperature in heating is preferably 350° C., more preferably 380° C., and still more preferably 400° C. The upper limit of the temperature is preferably 600° C., more preferably 550° C., and still more preferably 500° C. The lower limit of a heating time is preferably 15 seconds, more preferably 30 seconds. The upper limit of the time is preferably 1,200 seconds, and more preferably 600 seconds.

In the present disclosure, when the heating step is included, the order of the heating step and the processing step is not limited, and they may be performed in parallel, or one may be performed after the other, as long as the action and effect of the present disclosure are not impaired.

### [Organic Underlayer Film Forming Step]

In the step, before the resist pattern forming step, an organic underlayer film is formed directly or indirectly on the substrate having a metal-containing film after the processing step.

One example of a case where an organic underlayer film is indirectly formed on the substrate having a metal-containing film is a case where the organic underlayer film is formed on a surface modification film formed on the metal-containing film.

The organic underlayer film can be formed by applying a composition for forming an organic underlayer film. One example of a method for forming an organic underlayer film by coating with a composition for forming an organic underlayer film is a method in which the substrate having a resist underlayer film is directly or indirectly coated with a composition for forming an organic underlayer film, and a formed coating film is cured by heating or lithographic exposure. As the composition for forming an organic underlayer film, for example, “HM8006” manufactured by JSR Corporation can be used. Various conditions for heating or exposure can be appropriately determined according to the type of the composition for forming an organic underlayer film to be used.

### [Silicon-Containing Film Forming Step]

In the step, before the resist pattern forming step, a silicon-containing film is formed directly or indirectly on the substrate having a metal-containing film after the processing step.

One example of a case where a silicon-containing film is indirectly formed on the substrate having a metal-containing film is a case where a surface modification film or the organic underlayer film is formed on the metal-containing film.

The silicon-containing film can be formed by, for example, coating with a composition for forming a silicon-containing film, chemical vapor deposition (CVD), or atomic layer deposition (ALD). Examples of a method for forming a silicon-containing film by coating a composition for forming a silicon-containing film include a method including curing, by lithographic exposure and/or heating, a coating film formed by applying the composition for forming a silicon-containing film directly or indirectly to the metal-containing film. As a commercially-available product of the composition for forming a silicon-containing film, for example, “NFC SOG01”, “NFC SOG04”, “NFC SOG080” (which are all manufactured by JSR Corporation), or the like can be used. By chemical vapor deposition (CVD) or atomic layer deposition (ALD), a silicon oxide film, a silicon nitride film, a silicon oxynitride film, or an amorphous silicon film can be formed.

### [Resist Pattern Forming Step]

In this step, a resist pattern is formed directly or indirectly on the metal-containing film. Examples of a method for performing this step include a method using a resist composition, a method using nanoimprinting, and a method using a self-assembly composition. One example of a case where a resist pattern is indirectly formed on the metal-containing film is a case where, when the method for manufacturing a semiconductor substrate includes the silicon-containing film forming step, a resist pattern is formed on the silicon-containing film.

Specifically, the method using a resist composition is performed by applying a resist composition in such a manner that a resist film to be formed has a predetermined thickness and then volatilizing a solvent in a coating film by pre-baking to form a resist film.

Examples of the resist composition include a positive or negative chemically amplified resist composition containing a radiation sensitive acid generating agent, a positive resist composition containing an alkali-soluble resin and a quinonediazide-based photosensitizer, a negative resist composition containing an alkali-soluble resin and a crosslinking agent, and a metal-containing resist composition containing metals such as tin, zirconium, and hafnium. It should be noted that in this step, a commercially-available resist composition may directly be used.

Then, the formed resist film is subjected to exposure to light by selective irradiation with radiation. Radiation used for lithographic exposure can appropriately be selected depending on the type of radiation sensitive acid generating agent used in the resist composition, and examples thereof include electromagnetic rays such as visible rays, ultraviolet rays, far-ultraviolet, X rays, and γ rays and corpuscular rays such as electron rays, molecular rays, and ion beams. Among them, far-ultraviolet is preferred, KrF excimer laser light (248 nm), ArF excimer laser light (193 nm), F₂ excimer laser light (wavelength: 157 nm), Kr₂ excimer laser light (wavelength: 147 nm), ArKr excimer laser light (wavelength: 134 nm), or extreme ultraviolet (wavelength: 13.5 nm, hereinafter also referred to as “EUV”) is more preferred, and KrF excimer laser light, ArF excimer laser light, or EUV is even more preferred.

After the exposure to light, post-baking may be performed to improve resolution, pattern profile, developability, etc. The temperature and time of the post-baking may be appropriately determined according to the type or the like of the resist composition to be used.

Then, the exposed resist film is developed with a developer to form a resist pattern. This development may be either alkaline development or organic solvent development. Examples of the developer for alkaline development include basic aqueous solutions of ammonia, triethanolamine, tetramethylammonium hydroxide (TMAH), and tetraethylammonium hydroxide. To these basic aqueous solutions, for example, a water-soluble organic solvent such as an alcohol, e.g., methanol or ethanol, or a surfactant may be added in an appropriate amount. Examples of the developer for organic solvent development include various organic solvents mentioned above as examples of the solvent [B] contained in the composition.

After the development with a developer, a prescribed resist pattern is formed through washing and drying.

### [Etching Step]

In this step, a pattern is formed to the resist underlayer film by etching using the resist pattern as a mask. The number of times of etching may be once or twice or more, that is, etching may sequentially be performed using a pattern obtained by etching as a mask. However, from the viewpoint of obtaining a pattern having a further superior shape, etching is preferably performed twice or more. When performed a plurality of times, etching is performed to the silicon-containing film, the organic underlayer film, the resist underlayer film, and the substrate sequentially in order. Examples of an etching method include dry etching and wet etching. Among them, dry etching is preferred from the viewpoint of achieving a further superior pattern shape of the substrate. The dry etching uses, for example, gas plasma such as oxygen plasma. As a result of the etching, a semiconductor substrate having a prescribed pattern is obtained.

The dry etching can be performed using, for example, a known dry etching device. An etching gas used for the dry etching can appropriately be selected depending on, for example, a mask pattern or the elemental composition of a film to be etched, and examples thereof include a fluorine-based gas such as CHF₃, CF₄, C₂F₆, C₃F₈, or SF₆, a chlorine-based gas such as Cl₂ or BCl₃, an oxygen-based gas such as O₂, O₃, or H₂O, a reductive gas such as H₂, CO, CO₂, CH₄, C₂H₂, C₂H₄, C₂H₆, C₃H₄, C₃H₆, C₃H₈, HF, HI, HBr, HCl, NO, NH₃, or BCl₃, and an inert gas such as He, N₂, or Ar. These gases can also be used in admixture. When the substrate is etched using the pattern of the resist underlayer film as a mask, a fluorine-based gas is usually used.

### EXAMPLES

Hereinafter, Examples are described. The following Examples merely illustrate typical Examples of the present disclosure, and the Examples should not be construed to narrow the scope of the present disclosure.

The concentration of components other than the solvent in the mixture containing the compound [A] in this Example and the average thickness were measured by the methods described below.

[Concentration of Components Other than Solvent in Mixture Containing Compound [A]]

By firing 0.5 g of a mixture containing the compound [A] at 250° C. for 30 minutes, measuring a mass of the residue thus obtained, and dividing the mass of the residue by the mass of the solution containing the compound [A], the concentration (% by mass) of the components other than the solvent in the mixture containing the compound [A] was calculated.

### [Average Thickness of Film]

The average thickness of a film was determined by measuring the film thicknesses at arbitrary nine points at intervals of 5 cm including the center of the film formed on a silicon wafer using a spectroscopic ellipsometer (“M2000D” available from J. A. WOOLLAM) and calculating the average value of the film thicknesses.

### <Synthesis of Compound [A]>

The compound [m], the compound [x], the solvent [d], and the solvent [B] used for the synthesis of the compound [A] are listed below. In the following synthesis examples, unless otherwise specified, “parts by mass” means a value taken when the mass of the compound [m] used is 100 parts by mass. In addition, the “molar ratio” means a value taken when the amount of the compound [m] used is 1. The concentrations (% by mass) of components other than the solvent in the mixture containing the compound [A] are also shown in Table 1.

The following compounds were used as the compound [m].
m-1: Tetra-n-propoxyzirconium(IV)
m-2: Tetra-n-butoxyzirconium(IV)
m-3: Tetra-n-propoxyhafnium(IV)
m-4: Tetraisopropoxytitanium(IV)
m-5: Pentaethoxytantalum(V)
m-6: Tetramethoxytin(IV)
m-7: Tetraethoxytin(IV)
m-8: Tetra-n-propoxytin(IV)
m-9: Tetraisopropoxytin(IV)
m-10: Tetra-n-butoxytin(IV)
m-11: Tetraisobutoxytin(IV)
m-12: Tetra-sec-butoxytin(IV)
m-13: Tetra-tert-butoxytin(IV)
m-14: Pentaethoxytungsten(V)

The following compounds were used as the compound [x].
x-1: Propionic acid
x-2: Butyric acid
x-3: Isobutyric acid
x-4: Methacrylic acid
x-5:4-Vinylbenzoic acid
x-6:4-Ethynylbenzoic acid

The following compounds were used as the solvent [d].
d-1: n-Propyl alcohol
d-2: Ethanol
d-3:1-Butanol
d-4: Isopropanol
d-5: Methanol
d-6: Isobutanol
d-7: sec-Butanol
d-8: tert-Butanol

As the solvent [B], the following compounds were used.
B-1: Propylene glycol monomethyl ether acetate
B-2: Propylene glycol monomethyl ether

### [Synthesis Example 1-1] (Synthesis of Compound [A] (A-1))

The compound (m-1) (molar ratio of 1) and the solvent (d-1) (100 parts by mass) were charged into a reaction vessel under a nitrogen atmosphere. In the reaction vessel, the compound (x-1) (molar ratio: 5) was added with stirring at 50° C. The reaction was then conducted at 90° C. for 3 hours. After completion of the reaction, the inside of the reaction vessel was cooled to 30° C. or lower. After 900 parts by mass of the solvent (B-1) was added to the cooled reaction solution, the solvent (d-1), the alcohol generated via the reaction, and the excess solvent (B-1) were removed using an evaporator, thereby affording a mixture containing the compound (A-1). The concentration of components other than the solvent in the mixture containing the compound [A] (A-2) was 20% by mass.

### [Synthesis Examples 1-2 to 1-10 and 1-12 to 1-22] (Synthesis of Compounds [A] (A-2) to (A-10) and (A-12) to (A-22))

The compounds [A] (A-2) to (A-10), and (A-12) to (A-22) were obtained in the same manner as in Synthesis Example 1-1 except that the types and use amounts of the compound [m], the compound [x], the solvent [d], and the solvent [B] shown in the following Table 1 were used.

### [Synthesis Example 1-11] (Synthesis of Compound [A] (A-11))

The compound (m-3) (molar ratio of 1) and the solvent (d-1) (40 parts by mass) were charged into a reaction vessel under a nitrogen atmosphere. In the reaction vessel, the compound (x-4) (molar ratio: 5) was added with stirring at 50° C. The reaction was then conducted at 90° C. for 3 hours. After the completion of the reaction, the inside of the reaction vessel was cooled to 30° C. or lower. The precipitate obtained via the cooling was collected by filtration, washed with n-hexane (100 parts by mass), and then vacuum-dried, affording compound (A-11).

TABLE 1

| | | | | | | | | Concentration |
|---|---|---|---|---|---|---|---|---|
| | | | | | | | | of components |
| | | | | | | | | other than |
| | | | | | | | | solvent in |
| | | Compound [m] | | Compound [x] | | | | mixture containing |
| | Compound | | Molar | | Molar | Solvent [d] | Solvent [B] | compound [A] |
| | [A] | Type | ratio | Type | ratio | Type | Type | (% by mass) |
| Synthesis | A-1 | m-1 | 1 | x-1 | 5 | d-1 | B-1 | 20 |
| Example 1-1 | | | | | | | | |
| Synthesis | A-2 | m-1 | 1 | x-2 | 5 | d-1 | B-1 | 14 |
| Example 1-2 | | | | | | | | |
| Synthesis | A-3 | m-1 | 1 | x-3 | 5 | d-1 | B-1 | 14 |
| Example 1-3 | | | | | | | | |
| Synthesis | A-4 | m-1 | 1 | x-4 | 1 | d-1 | B-1 | 13 |
| Example 1-4 | | | | | | | | |
| Synthesis | A-5 | m-1 | 1 | x-4 | 2 | d-1 | B-1 | 13 |
| Example 1-5 | | | | | | | | |
| Synthesis | A-6 | m-1 | 1 | x-4 | 3 | d-1 | B-1 | 13 |
| Example 1-6 | | | | | | | | |
| Synthesis | A-7 | m-1 | 1 | x-4 | 5 | d-1 | B-1 | 20 |
| Example 1-7 | | | | | | | | |
| Synthesis | A-8 | m-1 | 1 | x-5 | 5 | d-1 | B-1 | 20 |
| Example 1-8 | | | | | | | | |
| Synthesis | A-9 | m-1 | 1 | x-6 | 5 | d-1 | B-1 | 20 |
| Example 1-9 | | | | | | | | |
| Synthesis | A-10 | m-2 | 1 | x-4 | 5 | d-3 | B-1 | 20 |
| Example 1-10 | | | | | | | | |
| Synthesis | A-11 | m-3 | 1 | x-4 | 5 | d-1 | — | 100 |
| Example 1-11 | | | | | | | | |
| Synthesis | A-12 | m-4 | 1 | x-3 | 5 | d-4 | B-1 | 13 |
| Example 1-12 | | | | | | | | |
| Synthesis | A-13 | m-5 | 1 | x-3 | 6 | d-2 | B-1 | 13 |
| Example 1-13 | | | | | | | | |
| Synthesis | A-14 | m-6 | 1 | x-1 | 5 | d-5 | B-2 | 20 |
| Example 1-14 | | | | | | | | |
| Synthesis | A-15 | m-7 | 1 | x-1 | 5 | d-2 | B-2 | 20 |
| Example 1-15 | | | | | | | | |
| Synthesis | A-16 | m-8 | 1 | x-1 | 5 | d-1 | B-2 | 20 |
| Example 1-16 | | | | | | | | |
| Synthesis | A-17 | m-9 | 1 | x-2 | 5 | d-4 | B-2 | 20 |
| Example 1-17 | | | | | | | | |
| Synthesis | A-18 | m-10 | 1 | x-3 | 5 | d-3 | B-2 | 20 |
| Example 1-18 | | | | | | | | |
| Synthesis | A-19 | m-11 | 1 | x-3 | 5 | d-6 | B-2 | 20 |
| Example 1-19 | | | | | | | | |
| Synthesis | A-20 | m-12 | 1 | x-4 | 5 | d-7 | B-2 | 20 |
| Example 1-20 | | | | | | | | |
| Synthesis | A-21 | m-13 | 1 | x-5 | 5 | d-8 | B-2 | 20 |
| Example 1-21 | | | | | | | | |
| Synthesis | A-22 | m-14 | 1 | x-3 | 6 | d-2 | B-2 | 20 |
| Example 1-22 | | | | | | | | |

### <Preparation of Composition>

The compound [A], the solvent [B], and other optional components [F] for use in preparation of the composition are described below.

The compounds (A-1) to (A-22) synthesized above were used as the compound [A].

The solvents (B-1) and (B-2) for use in synthesis of the compound [A] were used as the solvent [B].

The following compounds were used as the other optional components [F].
F-1:4-Methoxyphenol

### [Example 1-1] Preparation of Composition (J-1)

As shown in the following Table 2, a mixture containing the compound [A] (A-1) was mixed with (B-1) as the solvent [B] such that 7 parts by mass of components other than the solvent in the compound [A] (A-1) were mixed with 93 parts by mass of the solvent [B] (including the solvent [B] contained in the mixture containing the compound [A]). The resulting solution was filtered through a polytetrafluoroethylene (PTFE) filter having a pore size of 0.2 μm to prepare composition (J-1). “−” in the following Table 2 indicates that the corresponding component was not used.

### [Examples 1-2 to 1-10 and 1-12 to 1-22] Preparation of Compositions (J-2) to (J-10) and (J-12) to (J-22)

Compositions (J-2) to (J-10) and (J-12) to (J-22) were prepared in the same manner as in Example 1-1 except that the types and contents of the respective components were set as shown in the following Table 2.

### [Example 1-11] Preparation of Composition (J-11)

As shown in the following Table 2, 7 parts by mass of the compound [A] (A-11) were mixed with 92.995 parts by mass of (B-1) as the solvent [B] and 0.005 parts by mass of the other optional component [F] (F-1). The resulting solution was filtered through a polytetrafluoroethylene (PTFE) filter having a pore size of 0.2 μm to prepare composition (J-11).

TABLE 2

| | | Compound [A] | | | | | |
|---|---|---|---|---|---|---|---|
| | | or components | | | | Other | |
| | | other than solvent | | | | optional | |
| | | in mixture containing | | | | components | |
| | | compound [A] | | Solvent [B] | | [F] | |
| | | | Content | | Content | | Content |
| | Com- | | (Parts | | (Parts | | (Parts |
| | position | | by | | by | | by |
| | (J) | Type | mass) | Type | mass) | Type | mass) |
| Example 1-1 | J-1 | A-1 | 7 | B-1 | 93 | — | — |
| Example 1-2 | J-2 | A-2 | 7 | B-1 | 93 | — | — |
| Example 1-3 | J-3 | A-3 | 7 | B-1 | 93 | — | — |
| Example 1-4 | J-4 | A-4 | 7 | B-1 | 92.995 | F-1 | 0.005 |
| Example 1-5 | J-5 | A-5 | 7 | B-1 | 92.995 | F-1 | 0.005 |
| Example 1-6 | J-6 | A-6 | 7 | B-1 | 92.995 | F-1 | 0.005 |
| Example 1-7 | J-7 | A-7 | 7 | B-1 | 92.995 | F-1 | 0.005 |
| Example 1-8 | J-8 | A-8 | 4 | B-1 | 95.995 | F-1 | 0.005 |
| Example 1-9 | J-9 | A-9 | 4 | B-1 | 95.995 | F-1 | 0.005 |
| Example 1-10 | J-10 | A-10 | 7 | B-1 | 92.995 | F-1 | 0.005 |
| Example 1-11 | J-11 | A-11 | 7 | B-1 | 92.995 | F-1 | 0.005 |
| Example 1-12 | J-12 | A-12 | 7 | B-1 | 92.995 | F-1 | 0.005 |
| Example 1-13 | J-13 | A-13 | 7 | B-1 | 92.995 | F-1 | 0.005 |
| Example 1-14 | J-14 | A-14 | 7 | B-2 | 99 | — | — |
| Example 1-15 | J-15 | A-15 | 7 | B-2 | 99 | — | — |
| Example 1-16 | J-16 | A-16 | 7 | B-2 | 99 | — | — |
| Example 1-17 | J-17 | A-17 | 7 | B-2 | 99 | — | — |
| Example 1-18 | J-18 | A-18 | 7 | B-2 | 99 | — | — |
| Example 1-19 | J-19 | A-19 | 7 | B-2 | 99 | — | — |
| Example 1-20 | J-20 | A-20 | 7 | B-2 | 99 | — | — |
| Example 1-21 | J-21 | A-21 | 7 | B-2 | 99 | — | — |
| Example 1-22 | J-22 | A-22 | 7 | B-2 | 99 | — | — |

### <Evaluation>

For the compositions prepared in Examples 2-1 to 2-27 and Comparative Examples 2-1 to 2-23, in <Preparation of composition>, embeddability was evaluated by the following method. The evaluation results are shown together in the following Table 3.

### [Embeddability]

The composition was applied to a substrate with a trench pattern formed thereon having a depth of 30 nm and a width of 15 nm by spin coating using a spin coater (“LITHIUS Pro Z” available from Tokyo Electron Limited). The rotation condition of the spin coater was set such that a film-attached substrate with a film having an average thickness of 40 nm formed thereon after firing could be obtained. Next, T-1: UV irradiation at 100 mJ in an air atmosphere, T-2: UV irradiation at 500 mJ in an air atmosphere, T-3: UV irradiation at 1000 mJ in an air atmosphere, T-4: UV irradiation at 100 mJ in a nitrogen atmosphere, or T-5: oxygen plasma exposure (30 seconds) was performed. As a UV light source, a Xe excimer lamp (Ushio Inc., wavelength: 172 nm) was used. Next, H-1: heating at 400° C. for 60 seconds in a nitrogen atmosphere, or H-2: heating at 400° C. for 60 seconds in an air atmosphere, followed by cooling at 23° C. for 60 seconds. The sectional shape of the substrate was observed (200,000 magnifications) with a scanning electron microscope (“S-4800” available from Hitachi High-Technologies Corporation) to evaluate embeddability. The embeddability was evaluated as “A” (good) when the film was embedded to the bottom of the trench pattern of the substrate (namely, when there was no void), and evaluated as “B” (poor) when the film was not embedded to the bottom of the trench pattern (namely, when there was a void).

TABLE 3

| | | Processing | Heating | |
|---|---|---|---|---|
| | Composition | condition | condition | Embeddability |
| Example 2-1 | J-1 | T-1 | H-1 | A |
| Example 2-2 | J-1 | T-2 | H-1 | A |
| Example 2-3 | J-1 | T-3 | H-1 | A |
| Example 2-4 | J-1 | T-4 | H-1 | A |
| Example 2-5 | J-1 | T-5 | H-1 | A |
| Example 2-6 | J-1 | T-3 | H-2 | A |
| Example 2-7 | J-2 | T-3 | H-1 | A |
| Example 2-8 | J-3 | T-3 | H-1 | A |
| Example 2-9 | J-4 | T-3 | H-1 | A |
| Example 2-10 | J-5 | T-3 | H-1 | A |
| Example 2-11 | J-6 | T-3 | H-1 | A |
| Example 2-12 | J-7 | T-3 | H-1 | A |
| Example 2-13 | J-8 | T-3 | H-1 | A |
| Example 2-14 | J-9 | T-3 | H-1 | A |
| Example 2-15 | J-10 | T-3 | H-1 | A |
| Example 2-16 | J-11 | T-3 | H-1 | A |
| Example 2-17 | J-12 | T-3 | H-1 | A |
| Example 2-18 | J-13 | T-3 | H-1 | A |
| Example 2-19 | J-14 | T-3 | H-1 | A |
| Example 2-20 | J-15 | T-3 | H-1 | A |
| Example 2-21 | J-16 | T-3 | H-1 | A |
| Example 2-22 | J-17 | T-3 | H-1 | A |
| Example 2-23 | J-18 | T-3 | H-1 | A |
| Example 2-24 | J-19 | T-3 | H-1 | A |
| Example 2-25 | J-20 | T-3 | H-1 | A |
| Example 2-26 | J-21 | T-3 | H-1 | A |
| Example 2-27 | J-22 | T-3 | H-1 | A |
| Comparative | J-1 | None | H-1 | B |
| Example 2-1 | | | | |
| Comparative | J-1 | None | H-2 | B |
| Example 2-2 | | | | |
| Comparative | J-2 | None | H-1 | B |
| Example 2-3 | | | | |
| Comparative | J-3 | None | H-1 | B |
| Example 2-4 | | | | |
| Comparative | J-4 | None | H-1 | B |
| Example 2-5 | | | | |
| Comparative | J-5 | None | H-1 | B |
| Example 2-6 | | | | |
| Comparative | J-6 | None | H-1 | B |
| Example 2-7 | | | | |
| Comparative | J-7 | None | H-1 | B |
| Example 2-8 | | | | |
| Comparative | J-8 | None | H-1 | B |
| Example 2-9 | | | | |
| Comparative | J-9 | None | H-1 | B |
| Example 2-10 | | | | |
| Comparative | J-10 | None | H-1 | B |
| Example 2-11 | | | | |
| Comparative | J-11 | None | H-1 | B |
| Example 2-12 | | | | |
| Comparative | J-12 | None | H-1 | B |
| Example 2-13 | | | | |
| Comparative | J-13 | None | H-1 | B |
| Example 2-14 | | | | |
| Comparative | J-14 | None | H-1 | B |
| Example 2-15 | | | | |
| Comparative | J-15 | None | H-1 | B |
| Example 2-16 | | | | |
| Comparative | J-16 | None | H-1 | B |
| Example 2-17 | | | | |
| Comparative | J-17 | None | H-1 | B |
| Example 2-18 | | | | |
| Comparative | J-18 | None | H-1 | B |
| Example 2-19 | | | | |
| Comparative | J-19 | None | H-1 | B |
| Example 2-20 | | | | |
| Comparative | J-20 | None | H-1 | B |
| Example 2-21 | | | | |
| Comparative | J-21 | None | H-1 | B |
| Example 2-22 | | | | |
| Comparative | J-22 | None | H-1 | B |
| Example 2-23 | | | | |

As can be seen from the results in Table 3, the films formed from the compositions of Examples were superior in embeddability to Comparative Example.

By the method for manufacturing a semiconductor substrate of the present disclosure, a semiconductor substrate superior in embeddability of a composition for film formation in a substrate pattern can be obtained. Therefore, these can suitably be used for, for example, manufacturing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A method for manufacturing a semiconductor substrate, the method comprising:
applying a composition for film formation to a substrate to form a coating film, and
subjecting the coating film to at least one process selected from the group consisting of radiation exposure and plasma exposure,
wherein the composition for film formation comprises:
a metal compound comprising a metal atom and an organic acid, and
a solvent.

2. The method according to claim 1, wherein the metal atom belongs to Groups 3 to 16 of a periodic table.

3. The method according to claim 1, wherein the metal atom is at least one atom selected from the group consisting of titanium, zirconium, hafnium, tantalum, tungsten, and tin.

4. The method according to claim 1, wherein the organic acid is a carboxylic acid.

5. The method according to claim 1, wherein the substrate has a pattern.

6. The method according to claim 5, wherein the composition for film formation is embedded in the substrate having the pattern.

7. The method according to claim 5, wherein the pattern has a recess having a width of 20 nm or less.
